(19) United States
(12) Patent Application Publication
(10) Pub. No.: US 2025/0056944 A1
(43) Pub. Date: Feb. 13, 2025

(54) TOUCH-SENSITIVE ASSEMBLY AND METHOD FOR PRODUCING A TOUCH-SENSITIVE ASSEMBLY

(71) Applicant: ams-OSRAM International GmbH, Regensburg (DE)

(72) Inventors: Igor STANKE, Regensburg (DE); Marc PHILIPPENS, Regensburg (DE); Erwin LANG, Regensburg (DE)

(21) Appl. No.: 18/721,679

(22) PCT Filed: Dec. 16, 2022
(86) PCT No.: PCT/EP2022/086300

§ 371 Date: Jun. 19, 2024

(30) Foreign Application Priority Data
Dec. 20, 2021 (DE) 10 2021 133 900.6

(51) Int. Cl. H01L 33/62; G06F 3/041; G06F 3/042; G06F 3/044; H01L 25/075

(52) U.S. Cl. CPC H01L 33/62; G06F 3/0412; G06F 3/04164; G06F 3/042; G06F 3/0443; H01L 25/0753; G06F 2203/04103; G06F 2203/04108; H01L 2933/0066

(57) ABSTRACT

A touch-sensitive arrangement includes a carrier, an electrode layer, at least one light-emitting semiconductor body, and an encapsulation layer. The electrode layer is arranged between the carrier and the encapsulation layer and includes a first number N of detection areas and a second number M of illuminating areas. A detection area of the first number N of detection areas includes a first electrode. An illuminating area of the second number M of illuminating areas includes a first and a second contact connection line. The first contact connection line is coupled to a first terminal of the at least one light-emitting semiconductor body and the second contact connection line is coupled to a second terminal of the at least one light-emitting semiconductor body.

This patent application claims the priority of the German patent application 102021133900.6, the disclosure of which is hereby incorporated by reference.

A touch-sensitive arrangement, a device having a touch-sensitive arrangement, and a method for producing a touch-sensitive arrangement are disclosed.

A touch-sensitive arrangement is often used for the input of information or a command by a user to a device or machine. Such an arrangement can have light-emitting semiconductor bodies, such as LEDs, for illumination or backlighting. A foil equipped with LEDs and a touch-sensitive foil can, for example, be produced as separate foils and laminated to each other. Due to this dual function, the thickness of a touch-sensitive arrangement with light-emitting semiconductor bodies usually has a high value.

One object is to provide a touch-sensitive arrangement, a device having a touch-sensitive arrangement, and a method for producing a touch-sensitive arrangement, in which a thickness of the touch-sensitive arrangement is kept small.

These objects are solved by a touch-sensitive arrangement, a device with a touch-sensitive arrangement and a method for producing a touch-sensitive arrangement according to the independent claims. Further embodiments of the touch-sensitive arrangement, the device or the method are the subject of the dependent claims.

In at least one embodiment, a touch-sensitive arrangement comprises a carrier, an electrode layer, at least one light-emitting semiconductor body and an encapsulation layer. The electrode layer is arranged between the carrier and the encapsulation layer. The electrode layer comprises a first number N of detection areas and a second number M of illuminating areas. A detection area of the first number N of detection areas comprises a first electrode. An illuminating area of the second number M of illuminating areas comprises a first and a second contact connection line. The first contact connection line is coupled to a first terminal of the light-emitting semiconductor body. The second contact connection line is coupled to a second terminal of the at least one light-emitting semiconductor body.

The number of layers is advantageously kept low. This means that a low layer stack height is sufficient.

In at least one embodiment of the touch-sensitive arrangement, the detection area of the first number N of detection areas comprises the first electrode and a second electrode. The first electrode and the second electrode are at a distance from each other. In one example, the detection area of the first number N of detection areas is arranged such that an electric field between the first electrode and the second electrode protrudes from the encapsulation layer. Advantageously, the detection area of the first number N of detection areas is configured such that an electric field between the first electrode and the second electrode can be influenced by touching the encapsulation layer.

In at least one embodiment of the touch-sensitive arrangement, the electrode layer is realized from a metal. The metal contains copper, for example. The electrode layer is, for example, a copper layer.

In at least one embodiment of the touch-sensitive arrangement, the electrode layer comprises connection lines arranged as a grid. Advantageously, the electrode layer is not a continuous surface, but has openings. Therefore, the electrode layer is at least partially transparent.

In at least one embodiment of the touch-sensitive arrangement, a width B of a connection line of the grid is in a range between 0.5 μm and 50 μm or alternatively between 1 μm and 10 μm.

In at least one embodiment of the touch-sensitive arrangement, a connection line distance W of two parallel connection lines of the grid is in a range between 10 μm and 300 μm, alternatively between 50 μm and 200 μm. Thus, the width B of a connection line is smaller than the connection line distance W of two neighboring connection lines.

In at least one embodiment of the touch-sensitive arrangement, the distance A between the first electrode and the second electrode is greater than or equal to the connection line distance W.

In at least one further embodiment of the touch-sensitive arrangement, the distance A between the first electrode and the second electrode is smaller than the connection line distance W. In one example: W=200 μm and A=50 μm. In this case, the capacitor effect is increased as the distance between the electrodes is less than the connection line distance. The connection line distance has a particular effect on the transparency of the arrangement and the electrode distance has a particular effect on the capacitance.

In one example, the distance between the first electrode and the second electrode and/or the connection line distance are laterally different in the overall area of the touch-sensitive arrangement.

In at least one embodiment of the touch-sensitive arrangement, the first electrode comprises a third number L of parallel connection lines, wherein the third number L is greater than 1. Correspondingly, the second electrode comprises a fourth number K of parallel connection lines, wherein the fourth number K is greater than 1. In one example, the third number L and the fourth number K are identical.

In at least one embodiment of the touch-sensitive arrangement, the first electrode and the second electrode form an interdigital capacitor. Both the first electrode and the second electrode have a plurality of fingers.

In at least one embodiment of the touch-sensitive arrangement, the first electrode and the second electrode are arranged parallel to each other and in a meandering arrangement. Thus, the first electrode and the second electrode form a strip-line arrangement.

In at least one embodiment of the touch-sensitive arrangement, the at least one light-emitting semiconductor body is realized as a light-emitting diode, abbreviated as LED. The at least one light-emitting semiconductor body is arranged between the encapsulation layer and the electrode layer. The light-emitting diode is manufactured as a μLED or miniLED, for example.

In at least one embodiment of the touch-sensitive arrangement, the at least one light-emitting semiconductor body is realized as a micro light emitting diode (abbreviated to micro-LED, μ-LED or μLED). A micro LED is, for example, an LED with a particularly small size. In one example, a growth substrate is removed at a micro-LED so that typical heights or thicknesses of such micro-LEDs are in the range of 1.5 μm to 10 μm, for example; the micro-LED is therefore free of a growth substrate.

In one example, the micro-LED has a rectangular radiation emitting surface. In an alternative example, the micro-LED has a non-rectangular radiation emitting surface.

In one example, the micro-LED is realized as an LED with a radiation emitting area in which, in a top view of the layers of the layer stack, each lateral extension of the radiation emitting area is less than or equal to 100 μm or less than or equal to 70 μm.

In one example, the edge length of a rectangular micro-LED—particularly when viewed from above on the layers of the layer stack—is less than or equal to 70 μm or less than or equal to 50 μm.

In one example, such micro-LEDs are provided on wafers with non-destructively detachable holding structures for the micro-LED.

In one example, micro-LEDs are primarily used for displays. The micro-LEDs form pixels or sub-pixels and emit light of a defined color. Due to the small pixel size and high density with a short distance, micro LEDs are suitable for small monolithic displays, among other things. Micro LEDs can also be used in pixelated lighting arrangements, for example.

In at least one embodiment, the touch-sensitive arrangement comprises at least one photo sensor. The electrode layer comprises a sensor area. The sensor area is, for example, an optical sensor area. The sensor area comprises a first sensor connection line coupled to a first terminal of the photo sensor, and a second sensor connection line coupled to a second terminal of the photo sensor.

In at least one embodiment of the touch-sensitive arrangement, the carrier is realized as a film. The carrier is made of a polymer, for example. Alternatively, the carrier is realized as a glass, ceramic or semiconductor, such as silicon. The carrier may be referred to as a substrate.

In at least one embodiment of the touch-sensitive arrangement, the encapsulation layer is realized as a cover film or cover body. The encapsulation layer comprises, for example, glass or a polymer. The encapsulation layer is made, for example, of a glass or a polymer. The encapsulation layer is transparent. The encapsulation layer has, for example, a transmission of more than 1% or more than 10% or more than 90% in the visible spectral range. If necessary, a less transparent layer can also be used as the encapsulation layer. However, a very high transparency or transmission of more than 90% is advantageous, as the light should also be transmitted in the direction of encapsulation in the event of emission. If light is emitted in the opposite direction, a very low transmission would be suitable.

In at least one embodiment, the touch-sensitive arrangement comprises an intermediate layer that is electrically insulating. The intermediate layer is arranged on a first side at the electrode layer and the at least one light-emitting semiconductor body and is arranged on a second side at the encapsulation layer.

In at least one embodiment of the touch-sensitive arrangement, the intermediate layer comprises a polymer, such as polyvinyl butyral, abbreviated as PVB. Advantageously, the intermediate layer is formed as a hot melt adhesive. The intermediate layer serves to compensate for the different thicknesses of the electrode layer and the at least one light-emitting semiconductor body.

In at least one embodiment, the touch-sensitive arrangement is free of a further electrode layer disposed between the encapsulation layer and the electrode layer or between the electrode layer and a first side of the carrier or on the second side of the carrier.

In at least one embodiment, the touch-sensitive arrangement comprises a detection circuit coupled to the first electrode of a detection area of the first number N of detection areas. The detection circuit is configured, for example, to detect an approach of an object to the first electrode. The object is, for example, conductive. The object is, for example, a finger of a user. The detection circuit is configured, for example, to detect an approach of the object to the first electrode without using another electrode of the electrode layer. The detection circuit is configured, for example, to detect a change in a capacitance value between the first electrode and the object.

In at least one embodiment of the touch-sensitive arrangement, the detection circuit is coupled to the first electrode and the second electrode of a detection area of the first number N of detection areas. For example, the detection circuit is configured to detect an approach of an object to the first electrode and the second electrode. The first and second electrodes are realized such that an electric field between the first electrode and the second electrode is changed by the object. For example, the detection circuit is configured to detect a change in a capacitance value between the first electrode and the second electrode.

In at least one embodiment, the touch-sensitive arrangement is realized as a luminous film comprising a plurality of light-emitting semiconductor bodies.

In at least one embodiment, the touch-sensitive arrangement comprises at least one electrical control device coupled to the at least one light-emitting semiconductor body.

In at least one embodiment of the touch-sensitive arrangement, a semiconductor body of the at least one light-emitting semiconductor body has a thickness in a range of less than 300 μm, alternatively less than 100 μm or alternatively less than 5 μm.

In at least one embodiment, the touch-sensitive arrangement has a thickness of no more than 500 μm or alternatively no more than 200 μm or alternatively no more than 50 μm. The ranges ≤500 μm or ≤200 μm cover arrangements based on miniLEDs, for example. The range ≤50 μm covers the range of μLEDs (μLED is an abbreviation for micro-LED, for example), as these are generally much thinner (e.g. in the μm range). The thickness of the touch-sensitive arrangement is greater than the thickness of the light-emitting semiconductor body.

In at least one embodiment, the touch-sensitive arrangement is applied to an additional layer or is surrounded by additional layers. The additional layer or layers is, for example, a glass layer. The additional layer or layers may have a thickness in the range of a few mm.

In at least one embodiment of the touch-sensitive arrangement, the encapsulation layer and/or the carrier have characters, symbols or patterns. For example, a plurality of the light-emitting semiconductor bodies are arranged in the form of a character, symbol or pattern.

In at least one embodiment, a device comprises a touch-sensitive arrangement and an element from a group comprising a steering wheel of a vehicle, a dashboard of a vehicle, a control console of a vehicle, a device of mobile communication, a computer, a control console of a household appliance, a control console of a device of an industrial plant, a control console of a locking device and a control console of a toy and a window pane. The touch-sensitive arrangement is integrated in the element or applied to the element. The locking device is, for example, a door lock, a safe, a parcel station or a lock of a vehicle. The window pane is realized, for example, as the window pane of a car door, an entrance door or a shop window. The touch-sensitive arrangement is integrated into a transparent window pane of the car door, entrance door or shop window.

In one example, the touch-sensitive arrangement is realized as a keyboard of a computer. Alternatively, a keyboard comprises the touch-sensitive arrangement. The keyboard is connected to the computer or can be connected to the computer. The keyboard can be rolled up, for example. Advantageously, the touch-sensitive arrangement is flexible and can be manufactured with different widths and lengths, so that it can be realized as a rollable keyboard of a computer.

In at least one embodiment, a control console—e.g. a control console listed above—or a control element of an automobile has a three-dimensional shape (abbreviated to 3D shape). For example, the control element of an automobile can have a 3D shape in the area of the door (e.g. 3D shape of a switch).

In at least one embodiment, a method for producing a touch-sensitive arrangement comprises:
providing a carrier,
applying an electrode layer to the carrier,
applying at least one light-emitting semiconductor body to the electrode layer and
applying an encapsulation layer.

The electrode layer comprises a first number N of detection areas and a second number M of illuminating areas. A detection area of the first number N of detection areas comprises a first electrode. An illuminating area of the second number M of illuminating areas comprises a first and a second contact connection line. The first contact connection line is coupled to a first terminal of the light-emitting semiconductor body. The second contact connection line is coupled to a second terminal of the light-emitting semiconductor body.

The method described here is particularly suitable for producing the touch-sensitive arrangement described here. The features described in connection with the touch-sensitive arrangement can therefore also be used for the method and vice versa.

Advantageously, the electrode layer serves at least two electrical functions. A layer structure is therefore kept small. Advantageously, the touch-sensitive arrangement can be realized transparently.

In one example, the touch-sensitive arrangement realizes an integration of a touch detector with a luminous film. The touch-sensitive arrangement can realize an LED on foil or light in glass. The touch-sensitive arrangement is used, for example, in the automotive, transportation and/or building technology sectors and/or in the field of signage or security displays. The touch-sensitive arrangement can have display and design elements. It is advantageous that a touch function can be integrated without additional films. Advantageously, the touch-sensitive arrangement is flat, as no additional distance is required between the LEDs and the touch-sensitive film. The touch-sensitive arrangement is transparent.

Traditionally, touch-sensitive foils are often required to enable interaction with displays or display elements based on foil technology. Due to the high copper content in the wiring layer(s) of the LED foil, it is not possible to apply the two foils directly without a distance between them. Therefore, if a luminous film and a touch-sensitive film are laminated at a distance from each other, the flatness of the luminous film is lost. In contrast, the proposed touch-sensitive arrangement allows the touch functionality to be integrated directly into a film. This eliminates the need for an additional touch-sensitive film; the design remains flat; and work steps are also saved.

In one example, the assembly with light-emitting semiconductor bodies and the touch detection function are integrated on the same film.

In one example, a capacitance change between the first and second electrodes is measured for touch detection depending on whether, for example, an object such as a finger comes close to the surface of a detection area (also known as a switchable element). In order to be able to detect the largest possible capacitance difference, the first and second electrodes are designed in such a way that they protrude into each other like a comb. This allows the largest possible outer contour to be created between the two electrodes in a small area.

In an alternative example, the capacitance change of an electrode that the electrode has locally with respect to ground is detected for contact detection. The electrode comprises, for example, the first electrode, the second electrode, a parallel connection of the first and second electrodes or a series connection of the first and second electrodes. Advantageously, the surface area of the first electrode can be increased by adding the surface area of the second electrode to the surface area of the first electrode (in parallel or in series).

In one variant, a surface capacitor is integrated directly into the copper grid of the luminous foil by means of layout. A change in the total capacitance due to contact is detected. The application remains transparent by using the copper grid. In another variant, the crosstalk between two parallel meandering tracks integrated next to each other in the copper grid is measured. A modulated pulse current is introduced into the first track, crosstalk is picked up at the second track and measured. The touch-sensitive arrangement remains transparent by using the copper mesh. No additional components or work steps are required.

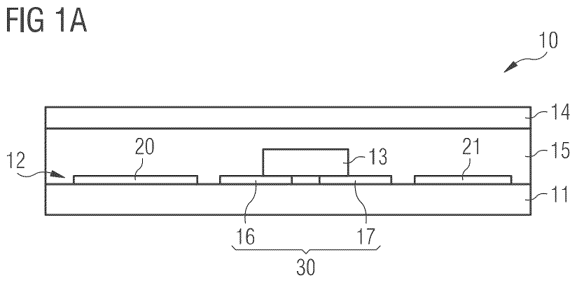

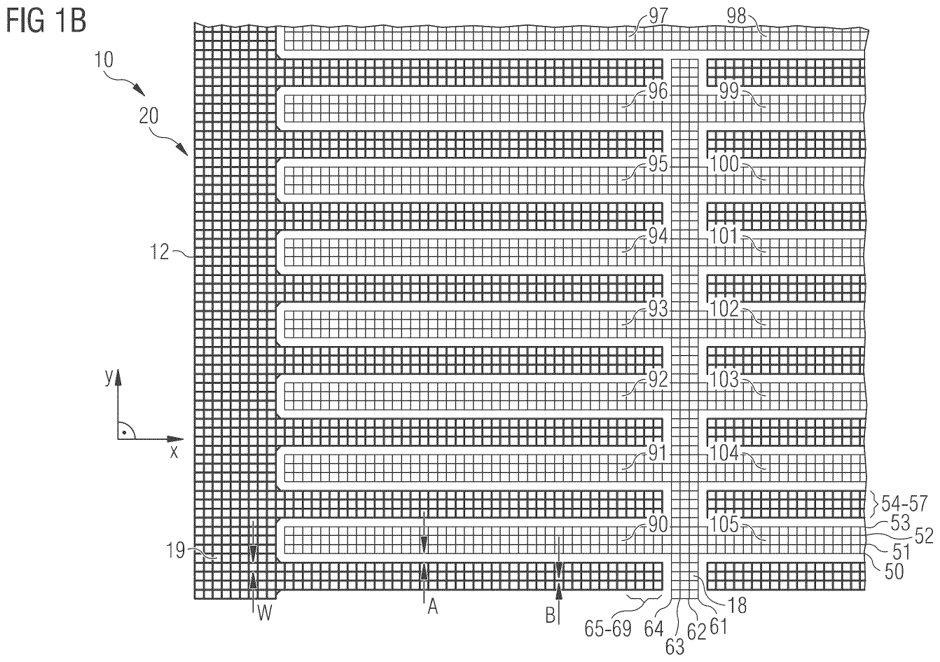

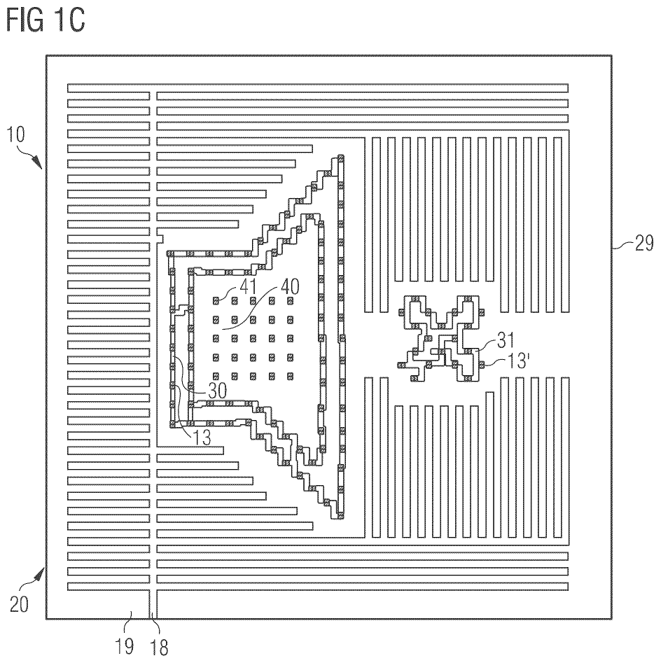

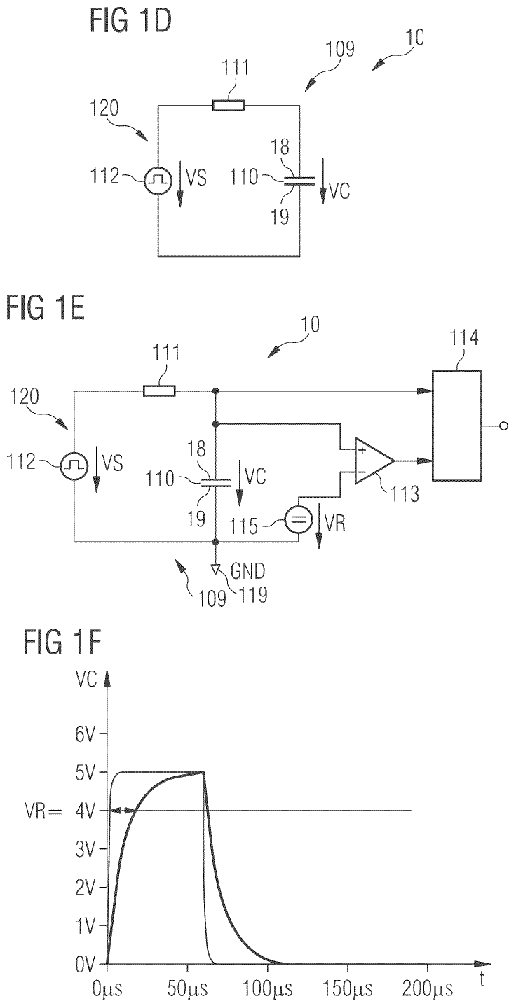

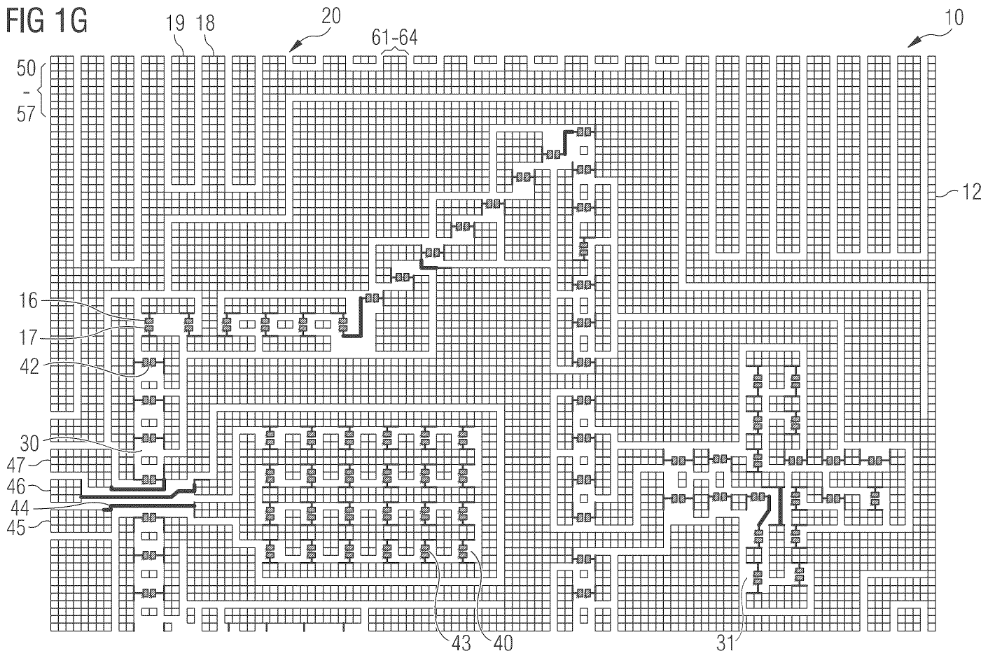

Further embodiments and further embodiments of the touch-sensitive arrangement or of the method for producing the touch-sensitive arrangement are shown in the embodiment examples explained below in conjunction with FIGS. 1 to 5. Structures, layers and components that are identical, similar or have the same effect are given the same reference symbols in the figures. They show

FIGS. 1A to 1G an embodiment of a touch-sensitive arrangement;

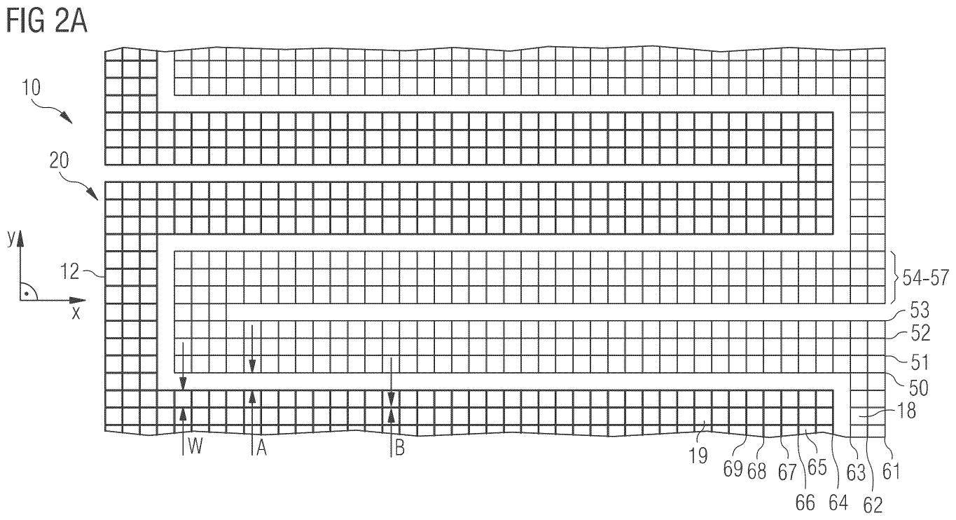

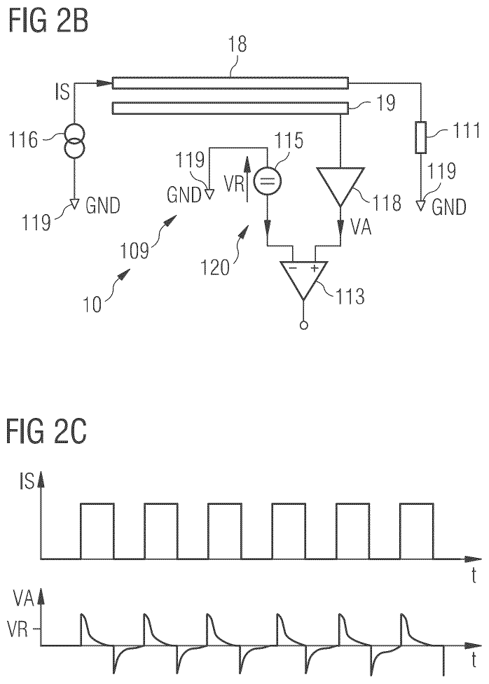

FIGS. 2A to 2C a further embodiment of a touch-sensitive arrangement;

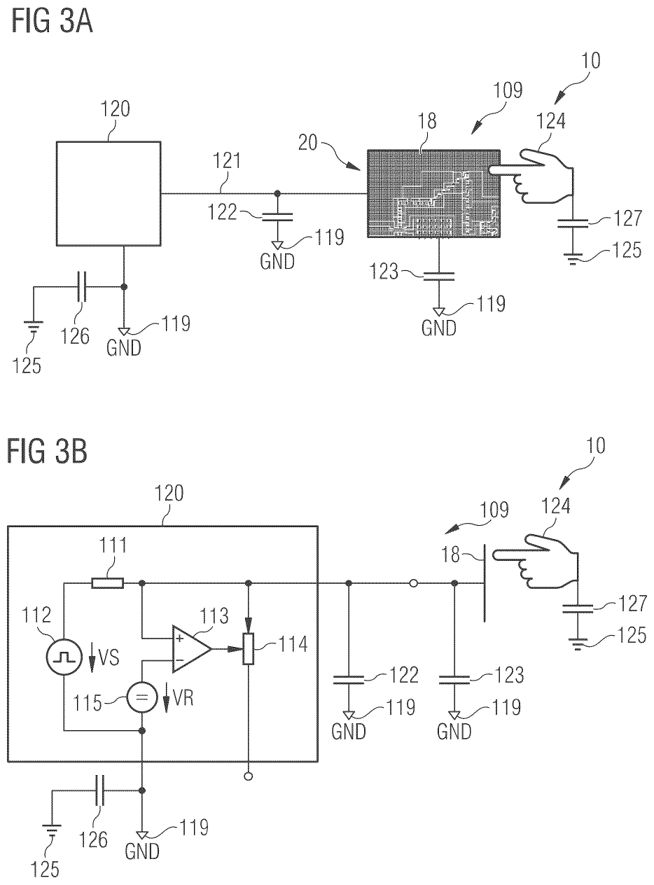

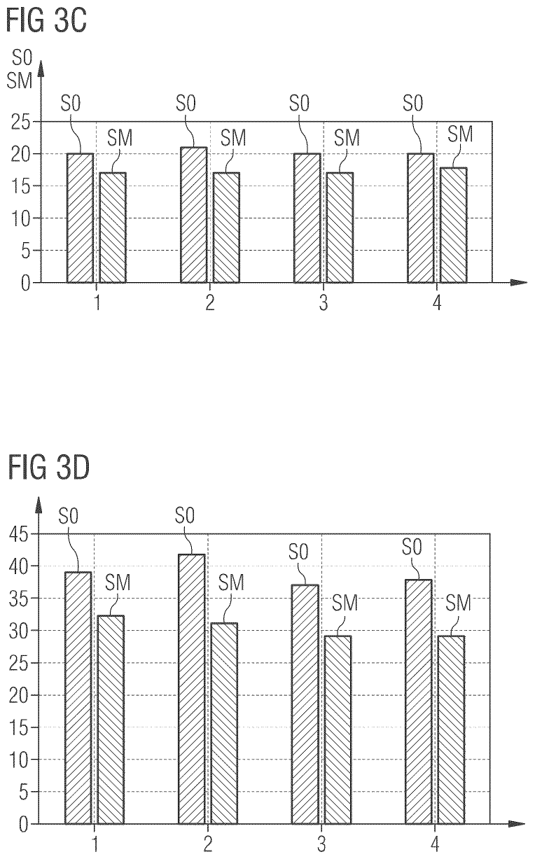

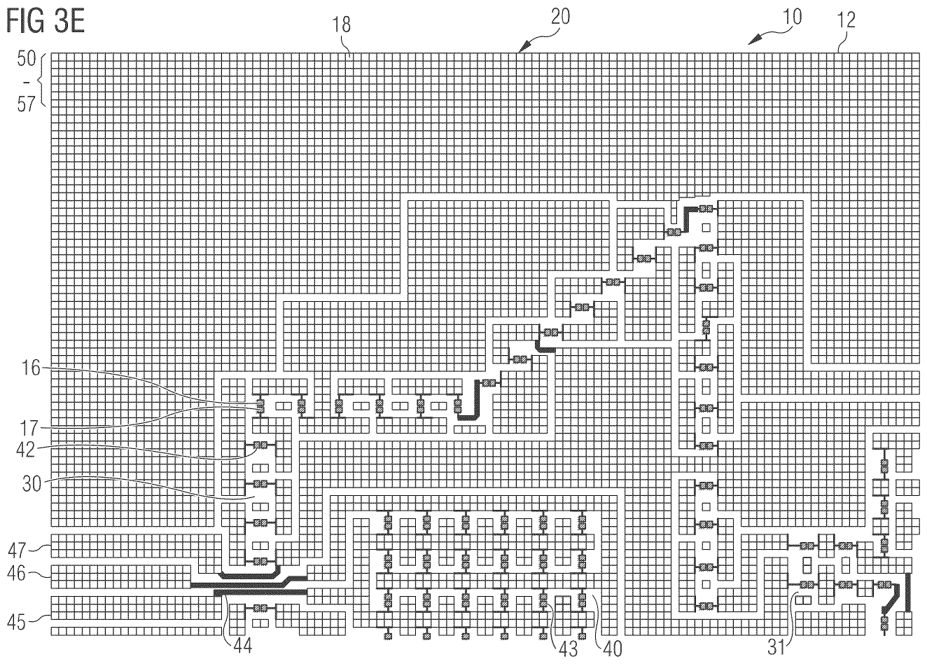

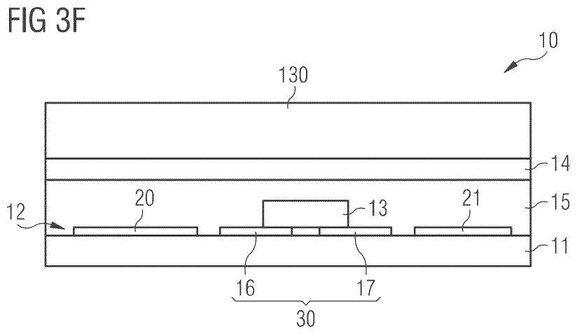

FIGS. 3A to 3F further embodiments of a touch-sensitive arrangement;

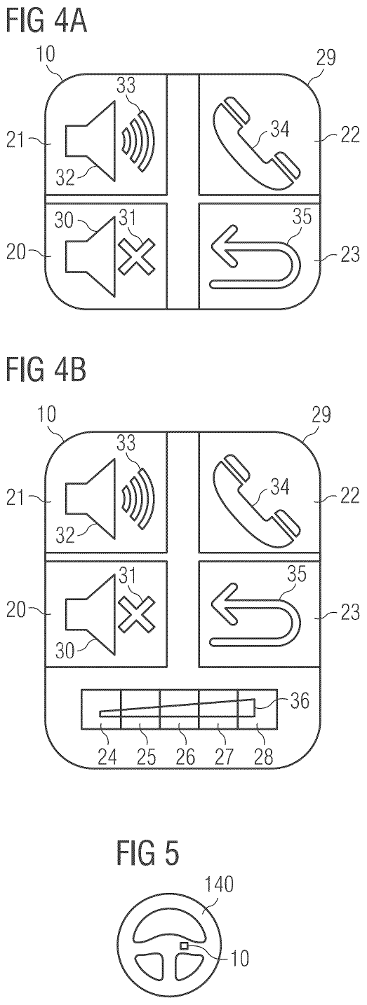

FIGS. 4A and 4B additional embodiments of a touch-sensitive arrangement; and

FIG. 5 an example of a device with a touch-sensitive arrangement.

FIG. 1A shows a cross-sectional view of an embodiment of a touch-sensitive arrangement 10. The touch-sensitive arrangement 10, abbreviated as arrangement, comprises a carrier 11, an electrode layer 12, at least one light-emitting semiconductor body 13 and an encapsulation layer 14. The carrier 11 can also be called a substrate. The carrier 11 is realized as a film. The electrode layer 12 is attached to the carrier 11. The electrode layer 12 comprises a metal. The metal is copper, for example. Thus, the electrode layer 12 is realized, for example, as a copper layer. The at least one light-emitting semiconductor body 13 is fixed to the electrode layer 12. The light-emitting semiconductor body 13 is arranged between the electrode layer 12 and the encapsulation layer 14. The encapsulation layer 14 is arranged above the light-emitting semiconductor body 13. The encapsulation layer 14 is made, for example, of a polymer or of glass.

In addition, the touch-sensitive arrangement 10 comprises an intermediate layer 15. The intermediate layer 15 is optional. The intermediate layer 15 is realized as an insulating intermediate layer. The intermediate layer 15 is arranged between the at least one light-emitting semiconductor body 13 and the encapsulation layer 14 and—at locations of the arrangement 10 without a light-emitting semiconductor body 13—between the electrode layer 12 or the carrier 11 and the encapsulation layer 14. On one side, the intermediate layer 15 is directly connected to the encapsulation layer 14. On the other side, the intermediate layer 15 is connected to the at least one light-emitting semiconductor body 13, the electrode layer 12 or the carrier 11.

The electrode layer 12 has a first number N of detection areas 20, 21 and a second number M of illuminating areas 30. A first illuminating area 30 of the second number M of illuminating areas 30 of the electrode layer 12 comprises a first and a second contact connection line 16, 17. In the example shown in FIG. 1A, the first number N is 2 and the second number M is 1.

A layer stack comprises the carrier 11/the electrode layer 12/the light-emitting semiconductor body 13/the encapsulation layer 14 or the carrier 11/the electrode layer 12/the light-emitting semiconductor body 13/the intermediate layer 15/the encapsulation layer 14.

Advantageously, the carrier 11 is printed on one side only. Advantageously, a layer stack of the touch-sensitive arrangement 10 has only a small number of layers.

The encapsulation layer 14 is electrically insulating, for example.

In an alternative embodiment, not shown, the touch-sensitive arrangement 10 is free of the intermediate layer 15. The encapsulation layer 14 is applied directly to the light-emitting semiconductor body 13, the electrode layer 12 and the carrier 11. The encapsulation layer 14 thus also assumes the function of the intermediate layer 15.

FIG. 1B shows an embodiment of the touch-sensitive arrangement 10, which is a further development of the embodiment shown in FIG. 1A. FIG. 1B shows a top view of a section of the first detection area 20. The first detection area 20 comprises a first and a second electrode 18, 19. The first and the second electrode 18, 19 form an interdigital capacitor. The first and second electrodes 18, 19 form a surface capacitor or grid capacitor. The interdigital capacitor has, for example, a capacitance of 1.2 pF.

The electrode layer 12 is realized as a grid. The electrode layer 12 has a plurality of parallel connection lines 50 to 57, which are parallel to an x-axis. One connection line of the plurality of parallel connection lines 50 to 57 has the shape of a straight line or a straight line section. Further, the electrode layer 12 has a plurality of parallel connection lines 61 to 69 that are parallel to a y-axis. One connection line of the plurality of parallel connection lines 61 to 69 has the shape of a straight line or a straight line section. The y-axis is perpendicular to the x-axis. The electrode layer 12 thus comprises a grid of mutually perpendicular connection lines. The grid is regular. The grid is rectangular. The first and second electrodes 18, 19 are realized in that connection lines are not continuous from the first electrode 18 to the second electrode 19 but are interrupted. According to FIG. 1B, a distance A between the first electrode 18 and the second electrode 19 is equal to a connection line distance W between two adjacent connection lines.

A width B of a connection line is smaller than the connection line distance W. The insulation from the first electrode 18 to the second electrode 19 is realized by interrupting the connection lines. The area between the first electrode 18 and the second electrode 19 can also be referred to as a trench.

A finger 90 to 105 of the first electrode 18 comprises a third number L of parallel connection lines 50-53. In the example shown in FIG. 1B, the third number L is equal to 4. The third number L can also be 1, 2, 3 or 5 or greater than 5. Typically, the third number L is greater than 1. Thus, an interruption of a connection line 50-53 of a finger does not lead to the total failure of the finger. Correspondingly, the second electrode 19 has fingers arranged between the fingers 90 to 105 of the first electrode 18. A finger of the second electrode 19 has a fourth number K of parallel connection lines. Typically, the fourth number K is greater than 1. In FIG. 1B, the third number L and the fourth number K are the same.

In an alternative embodiment, not shown, the distance A between the first electrode 18 and the second electrode 19 is greater than or equal to a multiple of the connection line distance W. The multiple is, for example, double, triple or quadruple. The distance A is, for example, the sum of the width B and twice the connection line distance W (A=2 W+B).

In an alternative embodiment, not shown, the grid is not rectangular.

In an alternative embodiment, not shown, one connection line of the plurality of connection lines has the shape of a curved curve.

FIG. 1C shows an embodiment of the touch-sensitive arrangement 10, which is a further development of the embodiment shown in FIGS. 1A and 1B. The section shown in FIG. 1B is shown at the bottom left of FIG. 1C. The touch-sensitive arrangement 10 comprises the second number M of illuminating areas 30, 31. In this example, the second number M is equal to 2. A plurality of light-emitting semiconductor bodies 13 is arranged on the first illuminating area 30 of the second number M of illuminating areas. A light-emitting semiconductor body 13 of the plurality of light-emitting semiconductor bodies 13 is realized as an LED. The plurality of light-emitting semiconductor bodies 13 is arranged in series or parallel to each other. The plurality of light-emitting semiconductor bodies 13 is coupled to the first and second contact connection lines 16, 17. A plurality of light-emitting semiconductor bodies 13′ is also placed on the second illuminating area 31 of the second number M of illuminating areas.

In top view, an illuminating area of the second plurality M of illuminating areas 30, 31 shows a pattern, figure or symbol. More specifically, the plurality of light-emitting semiconductor bodies 13 arranged on an illuminating area show a pattern, figure or symbol. In the example shown in FIG. 1C, the symbol shown by the first illuminating area 30 is a loudspeaker. The second illuminating area 31 represents an X in top view.

The touch-sensitive arrangement 10 comprises at least one photo sensor 41. The electrode layer 12 includes a sensor area 40. The sensor area 40 has a first sensor connection line (not shown) coupled to a first terminal of the photo sensor 41 and a second sensor connection line (not shown) coupled to a second terminal of the photo sensor 41. The sensor area 40 is localized within the first illuminating area 30.

An outer frame 29 of the electrode layer 12 is, for example, a rectangle, a square, an ellipse, a circle, or other shape. The first detection area 20 fills the area of the outer frame 29 of the electrode layer 12 that is not used by the second plurality M of illuminating areas. The first and second electrodes 18, 19 forming the interdigital capacitor are arranged around the first and second illuminating areas 30, 31. Advantageously, a large area of the detection area 20 is thus realized. With advantage, it is not important that a user has to hit a very small area to trigger a signal or enter information. With advantage, the light-emitting semiconductor bodies of the illuminating areas 30, 31 signal to the user the position of the desired detection area 20.

The first or second contact connection line can also be connected to the first or second electrode. In one example, the second contact connection line and the second electrode are connected to each other and connected to a reference potential. In this way, the number of external terminals can be kept low.

FIG. 1D shows an embodiment of a circuit arrangement 109 for a first detection area 20 as shown, for example, in FIGS. 1A to 1C. The first and second electrodes 18, 19 of the first detection area 20 form the electrodes of a capacitor 110. The circuit arrangement 109 comprises a detection circuit 120. The detection circuit 120 comprises a voltage source 112 and a resistor 111. The capacitor 110 is connected to the voltage source 112 via the resistor 111. The voltage source 112 outputs voltages in the form of square-wave pulses. The voltage pulses emitted by the voltage source 112 are used to charge the capacitor 110 via the resistor 111.

As can be seen in FIG. 1F, different capacitance values of the capacitor 110 result in different rise and decay behavior of a capacitor voltage VC at the capacitor 110. If the capacitance value of the capacitor 110 is high, the charging and discharging process of the capacitor 110 is slowed down. If, on the other hand, the capacitance value of the capacitor 110 is low, the rise and fall of the capacitor voltage VC are rapid.

The touch-sensitive arrangement 10 implements capacitive touch detection. The capacitor 110 between the two electrodes 18, 19 is used to detect touch. Touching the first detection area 20 acts as a parallel connection of an additional capacitor. Touch detection is performed, for example, by measuring the charging time.

FIG. 1E shows an embodiment of a circuit arrangement 109 for a first detection area 20, which is a further development of the embodiment shown in FIG. 1D. A comparator 113 of the detection circuit 120 compares the capacitor voltage VC with a reference voltage VR. The reference voltage VR is provided by a reference voltage source 115 of the detection circuit 120.

For example, an output of the comparator 113 and the output of the pulse-shaped voltage source 112 are fed to a time-interval measuring circuit 114 of the detection circuit 120. A rise of a pulse at the output of the voltage source 112 is fed to a start signal terminal of the time-interval measuring circuit 114. The output of the comparator 103 is fed to a stop signal input of the time-interval measuring circuit 114. The time-interval measuring circuit 114 determines the distance in time between the rising of the pulse signal VS and the capacitor voltage VC exceeding the reference voltage VR. A value of the time interval measured in this way is compared with a reference value. The time-interval measuring circuit 114 is implemented, for example, as a counter. The counter counts clock pulses of a clock signal supplied to the counter between the rising edge of the pulse at the start signal terminal and the rising edge of the pulse at the stop signal input of the time-interval measuring circuit 114.

Touching with a finger leads to an increase in the capacitance of the capacitor 110 of the first detection area 20. If the time value digitized by the time-interval measuring circuit 114 is greater than or equal to a reference value, the first detection area 20 has been touched. However, if the digitized time value is less than the reference value, the detection area 20 is free from being touched by the user.

FIG. 1F shows an embodiment for signal waveforms of a circuit arrangement 109 as shown, for example, in FIGS. 1D and 1E. The capacitor voltage VC is indicated as a function of a time t at a high and a low capacitance value of the capacitor 110.

In FIGS. 1D, 1E and 1F, only exemplary embodiments of the circuit arrangement 109 and of signals are shown in a schematic manner. The evaluation of the capacitance of the interdigital capacitor 110 of the first detection area 20 can also be done using alternative detection circuits, such as a capacitance-to-digital converter.

FIG. 1G shows an embodiment of the touch-sensitive arrangement 10, which is a further development of the embodiments shown in FIGS. 1A to 1F. In FIG. 1G, a section of the electrode layer 12 is shown. The first illuminating area 30 of the electrode layer 12 comprises contact areas 42. The contact areas 42 comprise the first and second contact connection lines 16, 17. The contact areas 42 are realized in such a way that a light-emitting semiconductor body 13 (not shown in FIG. 1G) can be arranged on the contact areas 42.

The sensor area 40 of the electrode layer 12 comprises further contact areas 43. The further contact areas 43 are realized in such a way that a photo sensor 41 (not shown in FIG. 1G) can be arranged on the further contact areas 43.

The electrode layer 12 comprises a further connection line 44. A width B′ of the further connection line 44 is greater than the width B of one of the connection lines 50 to 57 and 61 to 64. The width B′ is greater, for example, than twice the width B.

The electrode layer 12 comprises a connection line 45. The connection line 45 has a number of parallel connection lines, the number being greater than 1. The number may, for example, be equal to the third number L. The connection line 45 connects an outer terminal (not shown), for example to the further contact areas 43. The connection line 45 has, for example, the further connection line 44 in one section.

The electrode layer 12 has a plurality of contact lines 45 to 47 connecting outer terminals to the detection areas 20, the illuminating areas 30, 31 and the sensor area 40. The outer terminals of the electrode layer 12 are arranged near an edge of the carrier 11. Alternatively, the outer terminals of the electrode layer 12 are arranged close to two, three or four edges of the carrier 11.

FIG. 2A shows a further embodiment of a touch-sensitive arrangement 10, which is a further development of the embodiment shown in FIGS. 1A to 1G. In FIG. 2A, a top view of a section or detail of the first detection area 20 of the electrode layer 12 is shown. The first and second electrodes 18, 19 run parallel to each other. The first and second electrodes 18, 19 are each realized in a meandering shape. As in FIG. 1B, the first and second electrodes 18, 19 do not touch each other in FIG. 2A. The first and second electrodes 18, 19 thus form a strip conductor. A capacitance between the first and second electrodes 18, 19 is changed, namely increased, for example by a finger touching the encapsulation layer 14. The capacitance between the first and second electrodes 18, 19 can be evaluated similarly as shown in FIGS. 1D to 1F. Alternatively, touching the encapsulation layer 14 can be evaluated by a circuit arrangement 109 shown in FIG. 2B or another circuit arrangement.

FIG. 2B shows an embodiment of a circuit arrangement 109 that is a further development of the embodiments set forth above. The detection circuit 120 includes a current source 116 connected to the first electrode 18 (e.g., to a beginning of the first electrode 18). In one example, an end of the first electrode 18 is connected to a local reference potential terminal 119 via the resistor 111. A local reference potential GND is present at the local reference potential terminal 119. The comparator 113, for example, is connected to the second electrode 19. Optionally, an amplifier 118 is arranged between the second electrode 19 and an input of the comparator 113. The reference voltage source 115 is connected to the second input of the comparator 113.

As shown in FIG. 2C, the current source 116 emits a pulse-shaped current IS. There is a crosstalk of the pulses running on the first electrode 18 to the second electrode 23. If there is contact with the encapsulation layer 14, the crosstalk from the first electrode 18 to the second electrode 19 is so high that the comparator 113 detects that a crosstalk voltage VA is greater than the reference voltage VR and emits pulses at its output. If, on the other hand, there is no contact, the level of the crosstalk voltage VA on the second electrode 19 is so low that a constant signal is present at the output of the comparator 113.

The touch-sensitive arrangement 10 realizes an evaluation of a touch based on crosstalk. The crosstalk is measured for touch detection. The pulsed current source 116 is connected to the first electrode 18, which forms a first signal line. Touching the first detection area 20 increases the crosstalk between the signal lines realized by the two electrodes 18, 19. The frequency of the pulsed current source 116 is selected so as to minimize interferences.

FIG. 3A shows another embodiment of a touch-sensitive arrangement 10, which is a further development of the embodiments shown in FIGS. 1A to 1G and 2A to 2C. The first electrode 18 is connected to the detection circuit 120 via a terminal connection line 121. The first electrode 18 is coupled to the local reference potential terminal 119 via a parasitic capacitance 123. The terminal connection line 121 is also coupled to the local reference potential terminal 119 via a parasitic capacitance 122.

An object 124, such as a finger of a hand, approaches the first electrode 18. The encapsulation layer 14 or a layer stack comprising the encapsulation layer 14 and the intermediate layer 15 isolate the object 124 from the electrode layer 12 and thus from the first electrode 18. The object 124 has an object capacitance 127 to a ground 125. A ground capacitance 126 separates the local reference potential terminal 119 from the ground 125. The detection circuit 120 is free from a connection to the second electrode 19.

The touch-sensitive arrangement 10 realizes an integration of touch detection (also called touch functionality) and a carrier 11 of the light-emitting semiconductor bodies 13 (also called LED film) on the same substrate 11. The detection circuit 120 detects capacitance changes by detecting not the capacitance of the first and second electrodes 18, 19 with respect to each other, but the capacitance change of one electrode (e.g., the first electrode 18) with respect to the local reference potential terminal 119.

The first electrode 18 is arranged on the carrier 11 (also called LED substrate), for example, outside the first illuminating area 30 (also called LED emitting area). The detection circuit 120 measures the capacitance change of the first electrode 18 with respect to ground (local).

Optionally, the area of the first and second electrodes 18, 19 is measured as an arrangement (e.g., serial, parallel) with respect to ground 119; thereby an increase of the electrode area is achieved. Geometries of the first electrode 18 other than the comb structure are also possible. This results in a planar filling of the first detection area 20.

FIG. 3B shows another embodiment of a touch-sensitive arrangement 10, which is a further development of the above-mentioned embodiments. The detection circuit 120 is realized as shown in FIGS. 1D and 1E. The detection circuit 120 shown here is an example only.

FIGS. 3C and 3D show exemplary measurement results of the above-described embodiments of a touch-sensitive arrangement 10. In both figures, measurement results of a first number N of detection areas 20-23 are shown, wherein in this example the first number N is equal to four. The left-hand columns indicate a signal without contact SO and the right-hand columns indicate a signal with contact SM, each in artificial units. Depending on the detection circuit 120 selected, a measurement result may increase or decrease with increasing capacitance. In the examples shown in FIGS. 3C and 3D, the measurement results fall with increasing capacitance.

In FIG. 3C, the detection circuit 120 is connected to the first and second electrodes 18, 19 (as illustrated in FIGS. 1A to 1G). A relative change between the signal with contact SM and the signal without contact SO is in the range of 15% when the first electrode 18 and the second electrode 19 are used to detect the capacitance change between both electrodes 18, 19.

In FIG. 3D, the detection circuit 120 is connected exclusively to the first electrode 18 (as illustrated in FIGS. 3A and 3B). The relative change between the signal with contact SM and the signal without contact SO is in the range of 22% when the capacitance change of the first electrode 18 is measured against the local ground 119. During the measurements, the second electrode 19 is not connected. An even greater relative change in the signal is possible if the entire available area is used (as shown in FIG. 3E). Thus, the touch-sensitive arrangement 10 as shown in FIGS. 3A and 3B produces improved measurement results when comparing the state with contact to the state without contact compared to the measurement results with the two interdigitated electrodes 18, 19. It is possible to increase the electrode area or to achieve the same measurement signal with a smaller detection area. The larger measurement signals or measurement signal changes lead to a reduction in the time for the measurement and thus enable a faster feedback loop and consequently a higher sampling rate.

FIG. 3E shows a further embodiment of a touch-sensitive arrangement 10, which is a further development of the embodiments described above. A detection area 20 of the first number N of detection areas has exactly one electrode 18. The first detection area 20 of the first number N of detection areas has exactly the first electrode 18 and is free of the second electrode 19. It is free of a further electrode. The entire available area that is not used for symbol wiring is used as a touch-sensitive area. Consequently, it can be assumed that the relative change between the signal without touch SO and the signal with touch SM for the same area is greater than in the case of the measurements shown in FIGS. 3C and 3D.

FIG. 3F shows a further embodiment of a touch-sensitive arrangement 10, which is a further development of the above-mentioned embodiments. The touch-sensitive arrangement 10 comprises a covering element 130. The covering element 130 is insulating. The covering element 130 is connected to the encapsulation layer 14. The covering element 130 is provided on the side of the touch-sensitive arrangement 10 facing a user.

A layer stack comprises the carrier 11/the electrode layer 12/the light-emitting semiconductor body 13/the encapsulation layer 14/the covering element 130 or the carrier 11/the electrode layer 12/the light-emitting semiconductor body 13/the intermediate layer 15/the encapsulation layer 14/the covering element 130.

The covering element 130 is made of glass or a polymer, for example. The glass is, for example, quartz glass or borosilicate glass. The polymer is, for example, polymethyl methacrylate, also known as acrylic glass.

The covering element 130 has a thickness in a range between 100 μm and 3 mm, alternatively between 200 μm and 1200 μm, alternatively between 500 μm and 900 μm. For example, the thickness of the covering element 130 has a value of 700 μm. The covering element 130 may have laterally larger dimensions than, for example, the carrier 11, the electrode layer 12 or/and the encapsulation layer 14. The thinner the insulating layers over the electrode layer 12, the greater the sensitivity in detecting the approach of the object 124 to the touch-sensitive arrangement 10. The thicker the insulating layers over the electrode layer 12, the greater the robustness of the touch-sensitive arrangement 10.

FIG. 4A shows an embodiment of a touch-sensitive arrangement 10, which is a further development of the embodiments shown above. The touch-sensitive arrangement 10 has the second number M of illuminating areas 30-35. In FIG. 4A, the second number M is equal to 6. The first illuminating area 30 of the second number M of illuminating areas 30-35 symbolizes a loudspeaker and the second illuminating area 31 symbolizes an X or cross, as already shown in detail in FIG. 1C. A third illuminating area 33 symbolizes a loudspeaker, a fourth illuminating area 34 symbolizes sound waves, a fifth illuminating area 35 symbolizes a telephone receiver and a sixth illuminating area 36 symbolizes an arrow. The illuminating areas 30-35 shown in FIG. 4A are examples only and vary depending on the field of application.

The touch-sensitive arrangement 10 comprises a first number N of detection areas 20-23. In FIG. 4A, the first number N is equal to 4. The first detection area 20 is realized as in FIG. 1C. The first detection area 20 surrounds the first and second illuminating areas 30, 31. A second detection area 21 is arranged around the third and fourth illuminating areas 32, 33. A third and a fourth detection area 22, 23 are arranged around the fifth and the sixth illuminating area 34, 35. Thus, a detection area is typically arranged around at least one illuminating area. A detection area of the first number N of detection areas 20-28 thus surrounds at least one illuminating area of the second number M of illuminating areas 30-35.

In an alternative embodiment, not shown, a detection area does not enclose an illuminating area.

FIG. 4B shows a further embodiment of the touch-sensitive arrangement 10, which is a further development of the embodiments shown above. In addition, the touch-sensitive arrangement 10 comprises a series of detection areas 24-28. The series of detection areas 24-28 comprises at least two detection areas. The series of detection areas 24-28 is arranged, for example, in a linear fashion. The series of detection areas 24-28 allows values to be entered. For example, the series of detection areas comprises a number AN of detection areas 24-28. Thus, a number AN of values can be input. A control circuit coupled to the series of detection areas 24-28 can evaluate the value entered with the series of detection areas 24-28 and set, for example, a volume level or light intensity level.

In FIG. 4B, a further illuminating area 36 is associated with the series of detection areas 24 to 28. The light-emitting semiconductor bodies 13 of the further illuminating area 36 make the series of detection areas 24-28 visible. FIG. 4B thus illustrates a detection area 24 that does not completely enclose an illuminating area 36, but only partially encloses it. The series of detection areas 24 to 28 thus implements a slider.

FIG. 5 shows an embodiment of a device 140 with a touch-sensitive arrangement 10, which is a further development of the embodiments shown above. The device 140 is, for example, a steering wheel of a vehicle. Thus, the first number N of detection areas 20-28 are for inputting commands by a vehicle driver. The second number M of illuminating areas 30-36 enables easy recognition of the detection areas 20-28 to be touched, even in the dark.

The invention is not limited to the embodiments of the invention by the description thereof. Rather, the invention includes any new feature as well as any combination of features, which includes in particular any combination of features in the claims, even if this feature or combination itself is not explicitly stated in the claims or embodiments.

### LIST OF REFERENCE SYMBOLS

10 touch-sensitive arrangement
11 carrier
12 electrode layer
13 light-emitting semiconductor body
14 encapsulation layer
15 intermediate layer
16, 17 contact connection line
18, 19 electrode
20-28 detection area
29 outer frame
30-36 illuminating area
40 sensor area
41 photo sensor
42 contact area
43 further contact areas
44 further connection line
45-47 contact line
50-57 connection line
61-69 connection line
109 circuit arrangement
110 capacitor
111 resistor
112 voltage source
113 comparator
114 time interval measuring circuit
115 reference voltage source
116 current source
118 amplifier
119 local reference potential terminal
120 detection circuit
121 terminal connection line
122, 123 parasitic capacitance
124 object
125 ground
126 ground capacitance
127 object capacitance
130 covering element
140 device
A distance
B width
GND local reference potential
IS current
SM, SO signal
t time
VA crosstalk voltage
VC capacitor voltage
VR reference voltage
VS pulse signal
W connection line distance

1. A touch-sensitive arrangement comprising
a carrier,
an electrode layer,
at least one light-emitting semiconductor body and
an encapsulation layer,
wherein the electrode layer is arranged between the carrier and the encapsulation layer and comprises a first number N of detection areas and a second number M of illuminating areas,
wherein a detection area of the first number N of detection areas comprises a first electrode,
wherein an illuminating area of the second number M of illuminating areas comprises a first and a second contact connection line, and
wherein the first contact connection line is coupled to a first terminal of the at least one light-emitting semiconductor body and the second contact connection line is coupled to a second terminal of the at least one light-emitting semiconductor body.

2. The touch-sensitive arrangement according to claim 1,
wherein the electrode layer comprises connection lines arranged as a grid.

3. The touch-sensitive according to claim 2, wherein a width of a connection line of the grid is in a range between 0.5 μm and 20 μm.

4. The touch-sensitive arrangement according to claim 2,
wherein a connection line distance of two parallel connection lines of the grid is in a range between 30 μm and 300 μm.

5. The touch-sensitive arrangement according to claim 2,
wherein the first electrode comprises a third number L of parallel connection lines, and
where the third number L is greater than 1.

6. The touch-sensitive arrangement according to claim 1,
wherein a detection area of the first number N of detection areas comprises the first electrode and a second electrode and the first electrode and the second electrode have a distance from each other.

7. The touch-sensitive arrangement according to claim 6,
wherein a detection area of the first number N of detection areas is arranged such that an electric field between the first electrode and the second electrode protrudes from the encapsulation layer.

8. The touch-sensitive arrangement according to claim 6,
wherein a distance between the first electrode and the second electrode is greater than or equal to the connection line distance.

9. The touch-sensitive arrangement according to claim 6,
wherein the first electrode and the second electrode form an interdigital capacitor.

10. The touch-sensitive arrangement according to claim 6,
wherein the first electrode and the second electrode are arranged parallel to one another and in a meandering manner.

11. The touch-sensitive arrangement according to claim 1,
wherein the touch-sensitive arrangement comprises a detection circuit coupled to the first electrode of a detection area of the first number N of detection areas and configured to detect an approach of an object to the first electrode.

12. The touch-sensitive arrangement according to claim 1,
wherein the at least one light-emitting semiconductor body is arranged between the encapsulation layer and the electrode layer.

13. The touch-sensitive arrangement according to claim 1,
wherein the touch-sensitive arrangement comprises at least one photo sensor,
wherein the electrode layer comprises a sensor area, and
wherein the sensor area comprises a first sensor connection line coupled to a first terminal of the photo sensor and a second sensor connection line coupled to a second terminal of the photo sensor.

14. The touch-sensitive arrangement according to claim 1,
wherein the carrier is realized as a film and the encapsulation layer is realized as a cover film.

15. The touch-sensitive arrangement according to claim 1,
wherein the touch-sensitive arrangement comprises an intermediate layer which is electrically insulating, is arranged on a first side at the electrode layer and the at least one light-emitting semiconductor body and is arranged on a second side at the encapsulation layer.

16. The touch-sensitive arrangement according to claim 1,
wherein a semiconductor body of the at least one light-emitting semiconductor body has a thickness of less than 300 μm.

17. The touch-sensitive arrangement according to claim 1,
wherein the at least one light-emitting semiconductor body is realized as a micro-LED.

18. A device, comprising
a touch-sensitive arrangement according to claim 1 and
an element from a group comprising a steering wheel of a vehicle, a dashboard of a vehicle, a control console of a vehicle, a device of mobile communication, a computer, a control console of a household appliance, a control console of a device of an industrial plant, a control console of a locking device, a control console of a toy and a window pane,
wherein the touch-sensitive arrangement is integrated in the element or applied to the element.

19. A method for producing a touch-sensitive arrangement, comprising:
providing a carrier,
applying an electrode layer to the carrier,
applying at least one light-emitting semiconductor body to the electrode layer, and
applying an encapsulation layer,
wherein the electrode layer comprises a first number N of detection areas and a second number M of illuminating areas,
wherein a detection area of the first number N of detection areas comprises a first electrode,
wherein an illuminating area of the second number M of illuminating areas comprises a first and a second contact connection line, and
wherein the first contact connection line is coupled to a first terminal of the light-emitting semiconductor body and the second contact connection line is coupled to a second terminal of the light-emitting semiconductor body.

20. A touch-sensitive arrangement comprising
a carrier,
an electrode layer,
at least one light-emitting semiconductor body and
an encapsulation layer,
wherein the electrode layer is arranged between the carrier and the encapsulation layer and comprises a first number N of detection areas and a second number M of illuminating areas,
wherein a detection area of the first number N of detection areas comprises a first electrode,
wherein an illuminating area of the second number M of illuminating areas comprises a first and a second contact connection line,
wherein the first contact connection line is coupled to a first terminal of the at least one light-emitting semiconductor body and the second contact connection line is coupled to a second terminal of the at least one light-emitting semiconductor body, and
wherein the carrier is realized as a film and the encapsulation layer is realized as a cover film.
